(19) United States
(12) Patent Application Publication
(10) Pub. No.: US 2026/0130049 A1
(43) Pub. Date: May 7, 2026

(54) DISPLAY PIXEL CIRCUIT, ELECTRONIC DEVICE INCLUDING THE DISPLAY PIXEL CIRCUIT, AND METHOD OF MANUFACTURING THE DISPLAY PIXEL CIRCUIT

(71) Applicants: Samsung Display Co., Ltd., Yongin-si (KR); University Industry Foundation, Yonsei University, Seoul (KR)

(72) Inventors: TAESANG KIM, Yongin-si (KR); Hyun Jae KIM, Seoul (KR); JOON SEOK PARK, Yongin-si (KR); Jae Seong HAN, Seoul (KR)

(21) Appl. No.: 19/376,641

(22) Filed: Oct. 31, 2025

(30) Foreign Application Priority Data
Nov. 5, 2024 (KR) 10-2024-0154805

(51) Int. Cl. H10K 59/121; H10D 30/01; H10D 30/67; H10D 64/68; H10K 59/12

(52) U.S. Cl. CPC H10K 59/1213; H10D 30/0312; H10D 30/6736; H10D 30/6737; H10D 30/6755; H10D 64/689; H10K 59/1201

(57) ABSTRACT

A method of manufacturing a thin-film transistor in a display pixel circuit includes forming a gate electrode, forming, a gate insulating layer including a ferroelectric material on the gate electrode, forming a capping layer including a semiconductor layer on the gate insulating layer, and a metal layer on the semiconductor layer, wherein the semiconductor layer includes an oxide semiconductor, configuring the gate insulating layer to exhibit ferroelectricity, through a primary heat treatment process, and forming source/drain electrodes by patterning the metal layer.

### CROSS-REFERENCE TO RELATED APPLICATION

The present application claims priority to and the benefit of Korean Patent Application No. 10-2024-0154805, filed on Nov. 5, 2024, in the Korean Intellectual Property Office, the entire disclosure of which is incorporated herein by reference.

### BACKGROUND

### 1. Field

Embodiments of the present disclosure described herein are related to a display pixel circuit, an electronic device including the display pixel circuit and a method of manufacturing the display pixel circuit.

### 2. Description of the Related Art

In general, in display apparatuses such as organic light-emitting display apparatuses, transistors, connection electrodes, and wires are arranged in each sub-pixel to control the luminance, and/or the like of each sub-pixel.

The information disclosed in this Background section is intended to enhance understanding of the background of the disclosure and therefore it may contain information that does not constitute prior art.

### SUMMARY

Aspects according to one or more embodiments of the present disclosure are directed toward a display pixel circuit, in which the size of a pixel is reduced, and a method of manufacturing the display pixel circuit with a simplified process.

Additional aspects will be set forth in part in the description which follows and, in part, will be apparent from the description, or may be learned by practice of the presented embodiments of the disclosure.

According to one or more embodiments, a method of manufacturing a display pixel circuit including a switching thin-film transistor, a driving thin-film transistor connected to the switching thin-film transistor, and a light-emitting element connected to the driving thin-film transistor, includes forming the driving thin-film transistor, and forming the light-emitting element connected to the driving thin-film transistor, wherein the forming of the driving thin-film transistor includes forming a gate electrode, forming a gate insulating layer including a ferroelectric material on the gate electrode, forming a capping layer including a semiconductor layer on the gate insulating layer, and a metal layer on the semiconductor layer, wherein the semiconductor layer includes an oxide semiconductor, configuring the gate insulating layer to exhibit ferroelectricity, through a primary heat treatment process, and forming source/drain electrodes by patterning the metal layer.

In one or more embodiments, the method may further include, after the forming of the source/drain electrodes, patterning the semiconductor layer, and activating the semiconductor layer through a secondary heat treatment process.

In one or more embodiments, the forming of the source/drain electrodes and the patterning of the semiconductor layer may be performed by using a halftone mask.

In one or more embodiments, the method may further include, before the forming of the metal layer, patterning the semiconductor layer, and after the forming of the source/drain electrodes, activating the semiconductor layer through a secondary heat treatment process.

In one or more embodiments, the primary heat treatment process may be performed at a first temperature for a first period of time (e.g., about 30 seconds), and the secondary heat treatment process may be performed at a second temperature that is lower than the first temperature, for a second period of time that is longer than the first period of time.

In one or more embodiments, the ferroelectric material may include hafnium zirconium oxide (HZO), and the gate electrode and the metal layer may each include a material having a thermal expansion coefficient less than a thermal expansion coefficient of the ferroelectric material.

In one or more embodiments, the gate insulating layer may be formed by using at least one deposition method of an atomic layer deposition method, a sputtering deposition method, or a spin coating deposition method.

In one or more embodiments, the oxide semiconductor may include at least one material of InGaO (IGO), InZnO (IZO), InSnZnO (ITZO), or InGaZnO (IGZO).

In one or more embodiments, a thickness of the semiconductor layer may be about 5 nm to about 50 nm.

In one or more embodiments, a thickness of the gate insulating layer may be about 10 nm to about 20 nm.

In one or more embodiments, the method may further include, after the forming of the gate insulating layer, forming an additional gate insulating layer between the gate insulating layer and the semiconductor layer, wherein the additional gate insulating layer includes a dielectric material having a wider band gap than a band gap of the ferroelectric material.

In one or more embodiments, the additional gate insulating layer may include at least one material of silicon dioxide (SiO₂) or aluminum oxide (Al₂O₃).

In one or more embodiments, the gate electrode and the metal layer may each include at least one material of tungsten (W), platinum (Pt), molybdenum (Mo), or titanium nitride (TiN).

According to one or more embodiments, a display pixel circuit includes a switching thin-film transistor, a driving thin-film transistor connected to the switching thin-film transistor, and a light-emitting element connected to the driving thin-film transistor, wherein the driving thin-film transistor includes a gate electrode, a semiconductor layer including an oxide semiconductor, a gate insulating layer between the gate electrode and the semiconductor layer and including a ferroelectric material, and source/drain electrodes on the semiconductor layer, wherein the ferroelectric material includes hafnium zirconium oxide (HZO), and the gate electrode and the source/drain electrodes each include a material having a thermal expansion coefficient less than a thermal expansion coefficient of the ferroelectric material.

In one or more embodiments, the oxide semiconductor may include at least one material of InGaO (IGO), InZnO (IZO), InSnZnO (ITZO), or InGaZnO (IGZO).

In one or more embodiments, a thickness of the semiconductor layer may be about 5 nm to about 50 nm.

In one or more embodiments, a thickness of the gate insulating layer may be about 10 nm to about 20 nm.

In one or more embodiments, the display pixel circuit may further include an additional gate insulating layer between the gate insulating layer and the semiconductor layer, wherein the additional gate insulating layer includes a dielectric material having a wider band gap than a band gap of the ferroelectric material.

Here, the additional gate insulating layer may include at least one material of silicon dioxide (SiO₂) or aluminum oxide (Al₂O₃).

In one or more embodiments, the gate electrode and the metal layer may each include at least one material of tungsten (W), platinum (Pt), molybdenum (Mo), or titanium nitride (TiN).

Other aspects, features, advantages other than those described above will become apparent from the following drawings, claims, and a more detailed description of the present disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram schematically illustrating a display apparatus;

FIG. 2 is a circuit diagram illustrating a sub-pixel illustrated in FIG. 1, according to one or more embodiments;

FIG. 3 is a plan view illustrating the sub-pixel of FIG. 2, according to one or more embodiments;

FIGS. 4A-4H are cross-sectional views illustrating a method of manufacturing a display apparatus, according to one or more embodiments;

FIGS. 5A-5C are cross-sectional views illustrating a method of manufacturing a display apparatus, according to one or more embodiments;

FIG. 6 is a cross-sectional view illustrating a display apparatus according to one or more embodiments;

FIGS. 7A-7C, and FIGS. 8A and 8B are conceptual diagrams showing the operation principles of a thin-film transistor included in a display pixel circuit, according to one or more embodiments;

FIGS. 9A-9C are conceptual diagrams showing a result of an experiment conducted to determine the characteristics of a gate insulating layer of a thin-film transistor included in a display pixel circuit according to one or more embodiments, compared with a comparative example;

FIGS. 10A and 10B are conceptual diagrams showing a result of an experiment conducted to determine the characteristics of a semiconductor layer of a thin-film transistor included in a display pixel circuit according to one or more embodiments, compared with a comparative example; and

FIG. 11 is a conceptual diagram showing a result of an experiment conducted to determine the element characteristics of a thin-film transistor included in a display pixel circuit according to one or more embodiments, compared with a comparative example.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail herein, by referring to the drawings, to explain aspects of the present description. As used herein, the term “and/or” includes any and all combinations of one or more of (e.g., selected from among) the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As the present disclosure allows for one or more suitable changes and numerous embodiments, particular embodiments will be illustrated in the drawings and described in more detail. Advantages and features of the present disclosure and a method of achieving the same should become clear with embodiments described in more detail with reference to the drawings. However, the present disclosure is not limited to one or more embodiments disclosed herein, but may be implemented in one or more suitable forms.

In the following embodiments, terms such as “first,” “second,” and/or the like, are used only to distinguish one component from another, and such components must not be limited by these terms.

In the following embodiments, the singular expression also includes the plural meaning as long as it is not inconsistent with the context.

In n the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the following embodiments, if (e.g., when) a unit, region, or component is referred to as being “on” another unit, region, or component, it may be directly or indirectly on the other unit, region, or component, that is, one or more intervening units, regions, or components may be present therebetween.

In the following embodiments, if (e.g., when) a component is referred to as being “connected to” or “coupled to” another component, the component may be directly connected to or in direct contact with the other component or intervening components may be present therebetween, unless clearly defined otherwise in the context.

For convenience of description, the magnitude of components in the drawings may be exaggerated or reduced. For example, because the size and/or thickness of each component illustrated in the drawing are arbitrarily shown for convenience of description, the present disclosure is not necessarily limited to those illustrated in the drawing.

In the following examples, if (e.g., when) any one of one or more suitable components such as layers, films, regions, or plates, is referred to as being “on” another component, the component may be “directly on” the other component, or may be above the other component with yet another component therebetween. In addition, for convenience of description, the magnitude of components in the drawings may be exaggerated or reduced. For example, because the size and thickness of each component illustrated in the drawings are arbitrarily shown for convenience of description, the present disclosure is not necessarily limited to those illustrated in the drawing.

In the following embodiments, the x-axis, y-axis, and z-axis are not limited to three axes on a Cartesian coordinate system, and may be interpreted in a broad sense including them. For example, the x-axis, y-axis, and z-axis may be orthogonal to each other, but may refer to different directions that are not orthogonal to each other.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction the z-axis refers to a top-down view of the display panel, as if looking directly down onto the surface from above. In this context, the z-axis is the direction perpendicular or normal to the plane defined by the x-axis and the y-axis. This refers to that in a plan view, the arrangement of sub-pixels, pads, and other components as they are laid out on the substrate can be seen, without any perspective distortion.

Hereinafter, one or more embodiments will be described in more detail with reference to the accompanying drawings, and in describing one or more embodiments with reference to the drawings, the same or corresponding components are given the same reference numerals, and redundant descriptions thereof will not be provided.

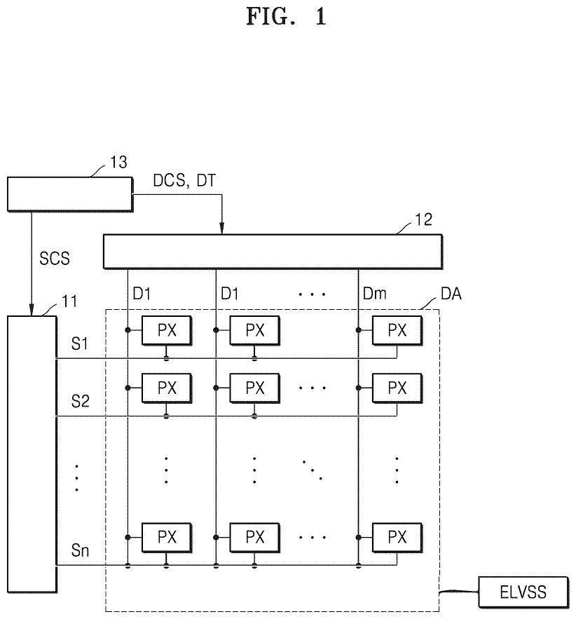

FIG. 1 is a block diagram schematically illustrating a display apparatus 10.

The display apparatus 10 according to one or more embodiment may be one or more suitable products, such as a smart phone, a tablet computer, a laptop computer, a television, or a billboard.

Referring to FIG. 1, the display apparatus 10 includes a display area DA including a plurality of sub-pixels PX located at intersection portions between scan lines S1, S2, . . . . Sn and data lines D1, D2, . . . , Dm, a scan driving circuit 11 configured to drive the scan lines S1, S2, . . . , Sn, a data driving circuit 12 configured to drive the data lines D1, D2, . . . , Dm, and a controller 13 configured to control the scan driving circuit 11 and the data driving circuit 12.

The scan driving circuit 11 receives a scan control signal SCS from the controller 13. The scan driving circuit 11 that has received the scan control signal SCS generates scan signals and sequentially supplies the generated scan signals to the scan lines S1, S2, . . . , Sn.

The data driving circuit 12 receives a data driving control signal DCS and data DT from the controller 13. The data driving circuit 12 that has received the data driving control signal DCS and the data DT generates data signals and supplies the generated data signals to the data lines D1, D2, . . . , Dm such that the data signals are synchronized with the scan signals.

The display area DA includes a plurality of sub-pixels PX located at intersection portions between the scan lines S1, S2, . . . , Sn and the data lines D1, D2, . . . , Dm.

The sub-pixels PX are selected if (e.g., when) scan signals are supplied from the scan lines connected to the sub-pixels PX, and emit light to the outside with luminances corresponding to the data signals supplied to the sub-pixels PX through the data lines, and accordingly, an image is displayed in the display area DA.

Hereinafter, an organic light-emitting display apparatus will be described in more detail as an example of a display apparatus according to one or more embodiments. However, a display apparatus according to one or more embodiments is not limited thereto. In one or more embodiments, the display apparatus of the present disclosure may be an inorganic light-emitting display apparatus, an inorganic electroluminescent (EL) display apparatus, or a quantum dot light-emitting display apparatus. For example, an emission layer of a display element included in the display apparatus may include an organic material or an inorganic material. In addition, the display apparatus may include an emission layer and a quantum dot layer located on the path of light emitted from the emission layer.

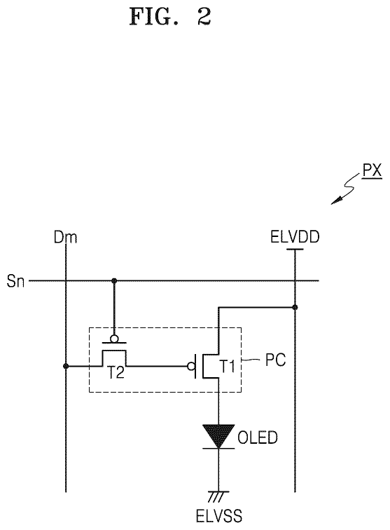

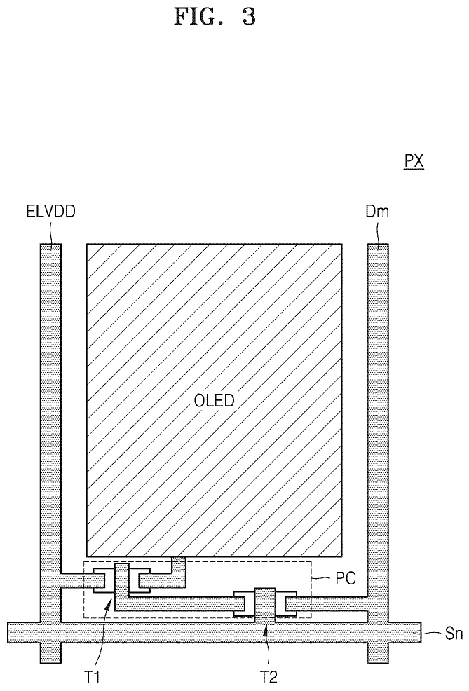

FIG. 2 is a circuit diagram illustrating the sub-pixel PX illustrated in FIG. 1, according to one or more embodiments. FIG. 3 is a plan view illustrating the sub-pixel PX of FIG. 2, according to one or more embodiments.

FIG. 2 illustrates the sub-pixel PX connected to an n-th scan line Sn and an m-th data line Dm.

Referring to FIGS. 2 and 3, the sub-pixel PX includes an organic light-emitting diode OLED and a pixel circuit PC. The pixel circuit PC is connected to the scan line and the data line to control light emission of the organic light-emitting diode OLED.

An anode electrode of the organic light-emitting diode OLED is electrically connected to the pixel circuit PC. In more detail, the anode electrode of the organic light-emitting diode OLED is connected to a driving transistor of the pixel circuit PC, and a cathode electrode of the organic light-emitting diode OLED is connected to a second pixel power supply ELVSS. The organic light-emitting diode OLED generates light with a luminance corresponding to a current supplied from the pixel circuit PC.

When a scan signal is supplied to the scan line, the pixel circuit PC controls the amount of current supplied to the organic light-emitting diode OLED, in correspondence with a data signal supplied from the data line.

The pixel circuit PC may include a plurality of thin-film transistors. In one or more embodiments, the pixel circuit PC includes a first thin-film transistor T1 and a second thin-film transistor T2. The first thin-film transistor T1 serves as a driving transistor, and the second thin-film transistor T2 serves as a switching transistor.

A first driving electrode of the first thin-film transistor T1 is connected to a first pixel power supply ELVDD, and a second driving electrode of the first thin-film transistor T1 is connected to the anode electrode of the organic light-emitting diode OLED. A driving gate electrode of the first thin-film transistor T1 is connected to the second thin-film transistor T2. Here, the first driving electrode may be a source electrode or a drain electrode, and the second driving electrode may be a drain electrode or a source electrode. In one or more embodiments, the first thin-film transistor T1 may be a ferroelectric field-effect transistor (FeFET) including an oxide semiconductor material in a semiconductor layer.

A first switching electrode of the second thin-film transistor T2 is connected to the data line, and a second switching electrode of the second thin-film transistor T2 is connected to the driving gate electrode of the first thin-film transistor T1. A switching gate electrode of the second thin-film transistor T2 is connected to the data line.

Here, the first switching electrode may be a source electrode or a drain electrode, and the second switching electrode may be a drain electrode or a source electrode. For example, the second thin-film transistor T2 may be an oxide semiconductor transistor (e.g., an oxide semiconductor thin-film transistor (TFT)) including an oxide semiconductor material in a semiconductor layer, rather than a ferroelectric field-effect transistor (FeFET).

The second thin-film transistor T2 is turned on if (e.g., when) a scan signal is supplied from the scan line, to supply, to the first thin-film transistor T1, a data signal supplied from the data line. According to one or more embodiments, the first thin-film transistor T1 is an FeFET, and thus has non-volatile memory characteristics. Thus, a voltage corresponding to the supplied data signal is stored in the first thin-film transistor T1. The first thin-film transistor T1 controls the amount of current flowing from the first pixel power supply ELVDD to the second pixel power supply ELVSS via the organic light-emitting diode OLED, in correspondence with a stored voltage value. The organic light-emitting diode OLED generates light corresponding to the amount of current supplied from the first thin-film transistor T1.

As described above, the first thin-film transistor T1 and the second thin-film transistor T2 may each include an oxide semiconductor material. In addition, an oxide semiconductor has high carrier mobility and low leakage current, and thus, a voltage drop may not be large even if (e.g., when) a driving time is long. For example, in an oxide semiconductor, a change in a color of an image according to a voltage drop is not large even if (e.g., when) the display apparatus is driven at low frequencies, and thus, the display apparatus may be driven at low frequencies. Accordingly, with a configuration in which a plurality of transistors include oxide semiconductor materials, it is possible to implement the display apparatus 10 having reduced power consumption while preventing or reducing the occurrence of a leakage current.

The first thin-film transistor T1 may have ferroelectric properties based on a gate insulating film associated with the driving gate electrode. The first thin-film transistor T1 exhibits ferroelectricity and thus has memory characteristics, and may operate as a non-volatile transistor. For example, the first thin-film transistor T1 may function as a storage element in addition to its role as a driving transistor within the pixel circuit PC. The first thin-film transistor T1 may also maintain a light-emitting state of the organic light-emitting diode OLED during a certain frame, based on the non-volatile memory characteristics.

In contrast, the second thin-film transistor T2 may not have ferroelectric properties. For example, the second thin-film transistor T2 may operate as a volatile transistor that does not have memory characteristics. For example, the second thin-film transistor T2 functions as a switching transistor within the pixel circuit PC.

According to one or more embodiments, the first thin-film transistor T1 of the pixel circuit PC is implemented as an FeFET by a ferroelectric material included in the gate insulating film associated with the driving gate electrode. Because FeFETs have nonvolatile memory characteristics, the first thin-film transistor T1 may also operate as a storage element. Thus, the display pixel circuit PC according to one or more embodiments does not require or may not include a (e.g., any) separate capacitor. For example, the display apparatus according to one or more embodiments may realize a reduced size of the sub-pixel PX by eliminating or not including a capacitor within the pixel circuit PC compared to comparable pixel circuit PC, enabling high resolution. For example, the display apparatus according to one or more embodiments may include a sub-pixel PX having a reduced size because sub-pixel PX may not include a capacitor within the pixel circuit PC, which may be included in a comparable pixel circuit, which may allow for higher resolution.

For example, the second thin-film transistor T2 may be an oxide semiconductor transistor (e.g., an oxide semiconductor thin-film transistor (TFT)) that includes an oxide semiconductor material in the semiconductor layer, rather than a ferroelectric field-effect transistor (FeFET). The first thin-film transistor (T1) may be implemented as an FeFET by incorporating a ferroelectric material in the gate insulating film, providing non-volatile memory characteristics. This allows the first thin-film transistor T1 to function as both a driving transistor and a storage element, eliminating the need for a separate capacitor and enabling a reduced sub-pixel size for higher resolution. In contrast, the second thin-film transistor T2 operates as a volatile switching transistor without memory characteristics. The use of oxide semiconductor materials in the transistors provides high carrier mobility and low leakage current, reducing power consumption and minimizing or decreasing voltage drops, even during prolonged operation.

### First Embodiment

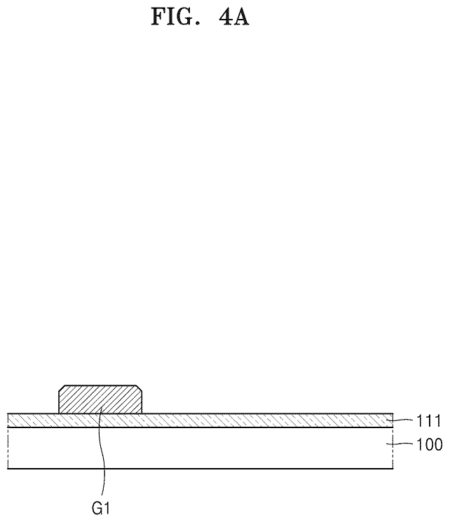

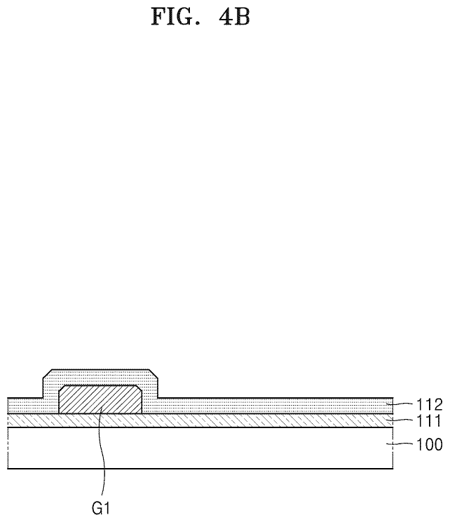

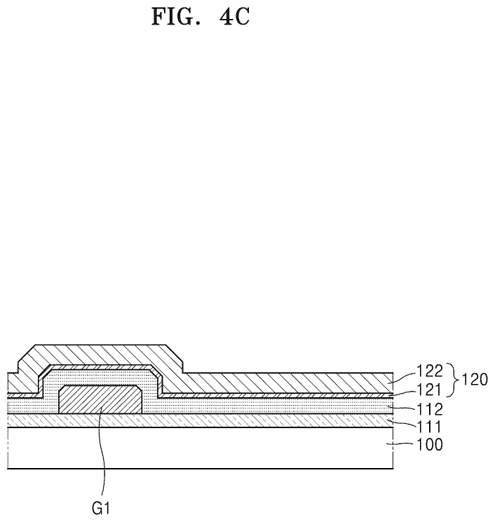

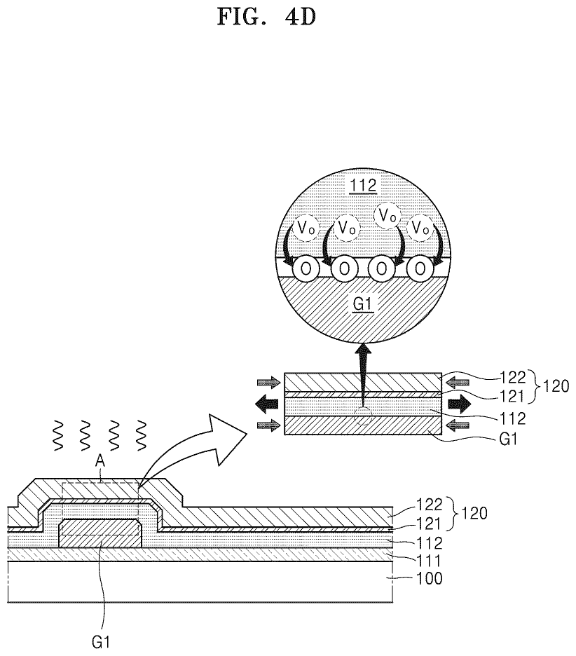

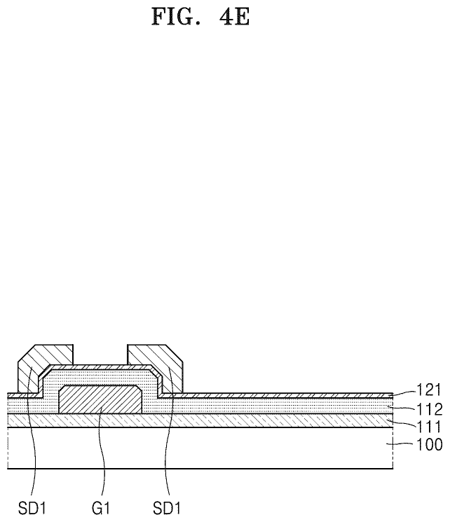

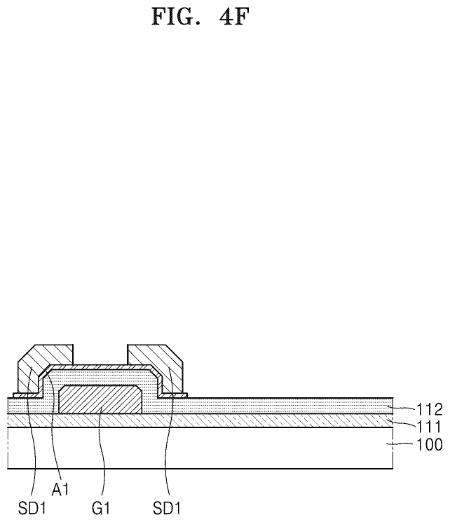

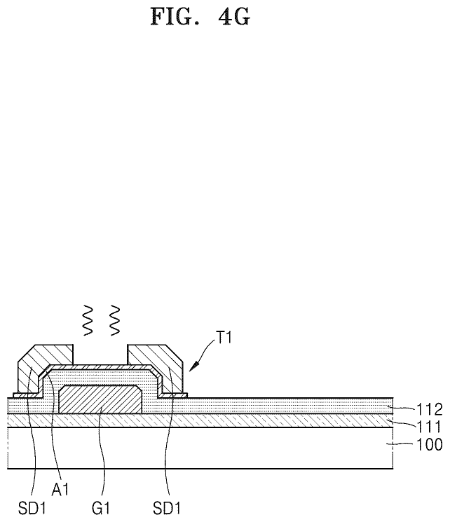

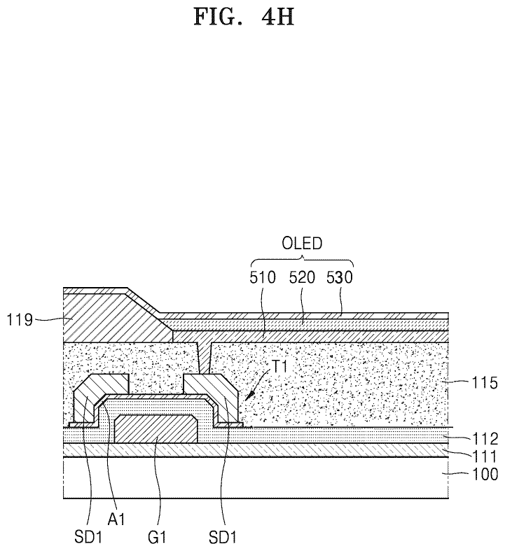

FIGS. 4A to 4H are cross-sectional views illustrating a method of manufacturing the display apparatus 10, according to one or more embodiments.

FIGS. 4A to 4H conceptually illustrate cross-sections of portions corresponding to the first thin-film transistor T1 and the organic light-emitting diode OLED of FIGS. 2 and 3, in the order of the manufacturing process. Because the sizes and/or thicknesses of components in the drawings are arbitrarily shown for convenience of description, the present disclosure is not necessarily limited to those illustrated in the drawings.

Referring to FIG. 4A, a barrier layer 111 including silicon oxide (SiOₓ), silicon nitride (SiNₓ), or silicon oxynitride (SiOₓN_{y}) may be located on a substrate 100. The barrier layer 111 may serve to planarize the upper surface of the substrate 100.

A first conductive layer is formed on the barrier layer 111. The first conductive layer is formed through sputtering or chemical vapor deposition (CVD) with a conductive material over the entire substrate. The conductive material may include a metal, an alloy, a transparent conductive material, and/or the like. For example, the first conductive layer may include one or more of (e.g., selected from among) silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), and/or scandium (Sc). In one or more embodiments, the first conductive layer may include a conductive material having a lower (less) coefficient of thermal expansion than ferroelectric materials. In one or more embodiments, the first conductive layer may include one or more materials of (e.g., selected from among) tungsten (W), platinum (Pt), molybdenum (Mo), and/or titanium nitride (TiN).

The first conductive layer may have a single-layer structure or may have a multilayer structure. The first conductive layer may have (e.g., may be formed to) a thickness of 200 nm to 700 nm. The first conductive layer may also be referred to as a gate layer for forming a gate electrode.

A gate electrode G1 is formed by patterning the first conductive layer. FIG. 4A illustrates a driving gate electrode included in the first thin-film transistor T1.

The patterning may be performed by applying a photoresist on the first conductive layer, selectively exposing the photoresist by irradiating the photoresist with light through a first mask, developing the photoresist, and forming a pattern on the exposed first conductive layer through wet etching or dry etching, which is suitable in the art, and thus, detailed descriptions thereof will not be provided. In one or more embodiments, the gate electrode may be formed through wet etching using a solution in which NH₃OH, H₂O₂, and H₂O are mixed in a ratio (e.g., amount) of 1:2:5.

Referring to FIG. 4B, a gate insulating layer 112 is formed on the gate electrode G1. The gate insulating layer 112 may be located on the barrier layer 111 to cover the gate electrode G1. The gate insulating layer 112 includes a ferroelectric material.

Ferroelectric materials have a spontaneous polarization (electric dipole moment) and the spontaneous polarization may be reversed in direction by an electric field. Ferroelectric materials have a spontaneous polarization therein in the absence of an electric field. In ferroelectric materials, the direction of a polarization changes if (e.g., when) the direction of an external electric field changes. Ferroelectric materials may maintain their polarization state even if (e.g., when) an external electric field disappears, and thus, elements that include ferroelectric materials on a gate insulating layer may be used as nonvolatile memory devices. The ferroelectric material may include one or more materials of (e.g., selected from among) lead zirconate titanate (PbZrₓ, Ti₁₋ₓO₃ (PZT)), barium titanate (BaTiO₃), and/or hafnium zirconium oxide (Hf_{0.5}Zr_{0.5}O₂ (HZO)). Hereinafter, an example will be described in more detail in which HZO among ferroelectric materials is used. HZO has higher back-end-of-line (BEOL) compatibility and scalability than other ferroelectric materials.

The gate insulating layer 112 is formed by depositing a ferroelectric material (e.g., HZO) over the entire substrate 100 by using one or more deposition methods of atomic layer deposition, sputtering deposition, and spin coating deposition. Hereinafter, an example will be described in in more detail in which the gate insulating layer 112 is formed through atomic layer deposition. In more detail, the gate insulating layer 112 may be formed through a process of forming a film with a thickness of 1.2 angstroms per cycle by using tetrakis(ethylmethylamido)hafnium (TEMAHf) and tetrakis(ethylmethylamido)zirconium (TEMAZr) as precursors in a ratio (e.g., amount) of 1:1.

According to one or more embodiments, the gate insulating layer 112 may have (e.g., may be formed to) a thickness of 10 nm to 20 nm. In a case in which the thickness of the gate insulating layer is less than 10 nm, electron tunneling occurs, which increases the leakage current, thus deteriorates or reduces the electrical characteristics of the element, resulting in insufficient or unsuitable ferroelectricity. That is, if (e.g., when) the thickness of the gate insulating layer is less than 10 nm, electron tunneling may occur. Electron tunneling may increase the leakage current and may reduce electrical characteristics of the element, which may result in unsuitable ferroelectricity. In addition, the element may be vulnerable to electrical stress or thermal stress, which may cause problems with the reliability or durability of the element. In a case in which the thickness of the gate insulating layer 112 is greater than 20 nm, there is a problem in that a bulk region, where the ferroelectricity of the gate insulating layer 112 is not exhibited, is formed in a central portion in the thickness direction.

Referring to FIG. 4C, a capping layer 120 is formed on the gate insulating layer 112. The capping layer 120 is formed through sputtering or CVD with a conductive material over the entire substrate 100.

According to one or more embodiments, the capping layer 120 may have a multilayer structure including a semiconductor layer 121 formed on the gate insulating layer 112, and a second conductive layer 122 formed on the semiconductor layer. For example, the semiconductor layer 121 may be between the second conductive layer 122 and the gate insulating layer 112.

The semiconductor layer 121 may include an oxide semiconductor. The oxide semiconductor may include an oxide of at least one material of (e.g., selected from among) indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and/or zinc (Zn). For example, the semiconductor layer 121 may include indium gallium oxide (IGO, InGaO), indium zinc oxide (IZO, InZnO), indium tin zinc oxide (ITZO, InSnZnO), indium gallium zinc oxide (IGZO, InGaZnO), and/or the like.

The semiconductor layer 121 may have (e.g., may be formed to) a thickness of 5 nm to 50 nm, or a thickness of 30 nm. In a case in which the thickness of the semiconductor layer 121 is less than 5 nm, the switching speed or on-off ratio of the element may decrease, resulting in deterioration or reduction of the electrical performance of the element. In a case in which the thickness of the semiconductor layer 121 is greater than 50 nm, a leakage current may occur, resulting in deterioration or reduction of the electrical characteristics of the element.

The second conductive layer 122 includes a conductive material (e.g., an electrically conductive material or conductor). The conductive material (e.g., an electrically conductive material or conductor) may include a metal, an alloy, a transparent conductive material, and/or the like. For example, the second conductive layer 122 may include one or more of (e.g., selected from among) silver (Ag), a silver-containing alloy, molybdenum (Mo), a molybdenum-containing alloy, aluminum (Al), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), and/or scandium (Sc).

In one or more embodiments, the second conductive layer 122 may include a conductive material (e.g., an electrically conductive material or conductor) having a lower (less) coefficient of thermal expansion than ferroelectric materials. In one or more embodiments, the second conductive layer 122 may be a metal layer including one or more materials of (e.g., selected from among) tungsten (W), platinum (Pt), molybdenum (Mo), and/or titanium nitride (TiN). In addition, the second conductive layer 122 may include the same material as the gate electrode. That is, the second conductive layer 122 and the gate electrode may include the same material.

The second conductive layer 122 may have a single-layer structure or may have a multilayer structure. The second conductive layer may have (e.g, may be formed to) a thickness of 200 nm to 700 nm, but the present disclosure is not limited thereto.

Referring to FIG. 4D, ferroelectricity is imparted to the gate insulating layer 112 through a primary heat treatment process. The primary heat treatment process may be a process of supplying heat of about 400° C. to about 600° C., or about 500° C., to the gate insulating layer 112 under a nitrogen environment (N₂ ambient) for about 20 seconds to about 40 seconds, or about 30 seconds, and then immediately cooling the gate insulating layer 112 (e.g., at a room temperature of 25° C.). In one or more embodiments, the primary heat treatment process may be a rapid thermal annealing (RTA) process. In more detail, referring to the enlarged view or portion A of FIG. 4D, the ferroelectric material included in the gate insulating layer 112 transitions to an orthorhombic phase (o-phase) through the RTA process, to form a particular crystal structure. The ferroelectric material that has transitioned to the o-phase exhibits electrical hysteresis and has a spontaneous polarization.

According to one or more embodiments, the capping layer 120 located on the upper surface of a gate insulating layer 112 including the ferroelectric material applies tensile stress to the gate insulating layer 112 in the primary heat treatment process. In particular, the capping layer 120 is formed as a double layer including the semiconductor layer 121 including an oxide semiconductor, and the metal layer 122 on the semiconductor layer 121, and thus may apply stronger tensile stress. In addition, because the gate electrode G1 located below the lower surface of the gate insulating layer 112, the gate electrode G1 also applies tensile stress to the gate insulating layer 112 in the primary heat treatment process. Accordingly, the gate insulating layer 112 may receive strong tensile stress from the sandwich structure. As described above, the capping layer 120 (the second conductive layer 122) and the gate electrode G1 each include a material having a lower coefficient of thermal expansion than the ferroelectric material included in the gate insulating layer 112, and thus, the structure according to one or more embodiments may efficiently apply tensile stress to the gate insulating layer 112 in the primary heat treatment process. For example, the capping layer 120 located on the upper surface of the gate insulating layer 112, which includes the ferroelectric material, applies tensile stress to the gate insulating layer 112 during the primary heat treatment process. Specifically, the capping layer 120 is a double layer composed of the semiconductor layer 121, which includes an oxide semiconductor, and the metal layer 122 on top of the semiconductor layer 121. This double layer structure may apply stronger tensile stress compared, e.g., to a single-layer structure. Additionally, the gate electrode G1, located below the lower surface of the gate insulating layer 112, also applies tensile stress to the gate insulating layer 112 during the primary heat treatment process. Consequently, the gate insulating layer 112 receives strong tensile stress from this sandwich structure. As described above, both the capping layer 120 (specifically, the second conductive layer 122) and the gate electrode G1 are made of materials with lower coefficients of thermal expansion than the ferroelectric material in the gate insulating layer 112. Therefore, this structure may efficiently apply tensile stress to the gate insulating layer 112 during the primary heat treatment process.

Referring to FIG. 4E, source/drain electrodes SD1 are formed by patterning the second conductive layer 122. FIG. 4E illustrates driving source/drain electrodes (corresponding to the first driving electrode and/or the second driving electrode of FIG. 2) included in the first thin-film transistor T1.

The patterning may be performed by applying a photoresist on the second conductive layer 122, selectively exposing the photoresist by irradiating the photoresist with light through a second mask, developing the photoresist, and forming a pattern on the exposed second conductive layer 122 through wet etching or dry etching, which is suitable in the art, and thus, detailed descriptions thereof will not be provided. In one or more embodiments, the source/drain electrodes SD1 may be formed through wet etching using a solution in which NH₃OH, H₂O₂, and H₂O are mixed in a ratio (e.g., amount) of 1:2:5.

Referring to FIG. 4F, the exposed semiconductor layer 121 is patterned. The patterned semiconductor layer 121 includes a driving semiconductor area A1 of the first thin-film transistor T1.

The patterning according to one or more embodiments may be performed by applying a photoresist on the semiconductor layer 121, selectively exposing the photoresist by irradiating the photoresist with light through a third mask, developing the photoresist, and forming a pattern on the exposed semiconductor layer 121 through wet etching or dry etching, which is suitable in the art, and thus, detailed descriptions thereof will not be provided. In one or more embodiments, the semiconductor area A1 may be formed through wet etching using a diluted hydrochloric acid (HCl) solution in which HCl and water are mixed in a ratio (e.g., amount) of 1:10.

In one or more embodiments, the process of patterning the second conductive layer 122 of FIG. 4E and the process of patterning the semiconductor layer 121 of FIG. 4F may be performed by a single halftone mask. According to one or more embodiments, the masking process may be performed in one stage, which may enable simplification of the manufacturing process.

Referring to FIG. 4G, the patterned semiconductor area A1 is activated. In more detail, the patterned semiconductor area A1 is activated through a secondary heat treatment process, and the on-off ratio of the activated semiconductor area A1 may be approximately 10⁸ (10 to the power of 8). The semiconductor area A1 exhibits metallic characteristics after the primary heat treatment process, and is thus not suitable for channel formation. Thus, transfer characteristics may be imparted to the semiconductor area A1 by the secondary heat treatment process. The electron mobility of the semiconductor area A1 may be improved by changing the semiconductor area A1 into an active region through the secondary heat treatment process.

The secondary heat treatment process may be a process of supplying heat of about 200° C. to about 350° C., or about 300° C., to the patterned semiconductor area A1 under an air environment (e.g., air ambient) for about 50 minutes to about 70 minutes, or about 60 minutes, and then immediately cooling the semiconductor area A1 (e.g., at a room temperature of 25° C.). The secondary heat treatment process may be a furnace annealing process.

The secondary heat treatment process is performed at a lower temperature and for a longer period of time than the primary heat treatment process. By performing substantially uniform heat treatment for a relatively long period of time, the substantially uniform characteristics of the oxide semiconductor layer are corrected or improved, oxygen vacancies in the oxide semiconductor layer may be effectively corrected or improved, and a highly reliable element may be manufactured with less thermal stress due to low temperatures.

Referring to FIG. 4H, an interlayer insulating layer/planarization layer 115 is formed on the gate insulating layer 112 to cover the source/drain electrodes SD1. The interlayer insulating layer/planarization layer 115 may include an insulating material. For example, the interlayer insulating layer/planarization layer 115 may include silicon oxide, silicon nitride, silicon oxynitride, aluminum oxide, and/or the like. As another example, the interlayer insulating layer/planarization layer 115 may include an organic insulating material. For example, the interlayer insulating layer/planarization layer 115 may include a photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a (e.g., any suitable) mixture thereof.

The organic light-emitting diode OLED may be located on the interlayer insulating layer/planarization layer 115. The organic light-emitting diode OLED may include a pixel electrode 510, an intermediate layer 520 including an emission layer, and an opposite electrode 530.

The pixel electrode 510 may be a (semi) transparent electrode or a reflective electrode. For example, the pixel electrode 510 may include a reflective layer including Ag, Mg, Al, Pt, Pd, Au, Ni, Nd, Ir, Cr, or a compound thereof, and a transparent or semitransparent electrode layer located on the reflective layer. The transparent or semitransparent electrode layer may include at least one of indium tin oxide (ITO), indium zinc oxide (IZO), zinc oxide (ZnO), indium oxide (In₂O₃), indium gallium oxide (IGO), or aluminum zinc oxide (AZO). For example, the pixel electrode 510 may have a three-layer structure of ITO/Ag/ITO.

A pixel-defining film 119 may be arranged on the interlayer insulating layer/planarization layer 115. The pixel-defining film 119 may increase the distance between an edge of the pixel electrode 510 and the opposite electrode 530 above the pixel electrode 510, and thus prevent or reduce arcs and/or the like from occurring at the edge of the pixel electrode 510. The pixel-defining film 119 may include (e.g., may be formed of) one or more organic insulating materials of (e.g., selected from among) polyimide, polyamide, acrylic resin, benzocyclobutene, and/or phenol resin, by using a method such as spin coating.

At least a portion of the intermediate layer 520 of the organic light-emitting diode OLED may be located inside an opening formed by the pixel-defining film 119. A light-emitting area of the organic light-emitting diode OLED may be defined by the opening.

The intermediate layer 520 may include an emission layer. The emission layer may include an organic material including a fluorescent or phosphorescent material that emits red, green, blue, or white light. The emission layer may include a low-molecular organic material or a high-molecular organic material, and functional layers such as a hole transport layer (HTL), a hole injection layer (HIL), an electron transport layer (ETL), and an electron injection layer (EIL) may be selectively arranged below and on the emission layer.

The emission layer may have a patterned shape corresponding to each of the pixel electrodes 510. Layers other than the emission layer included in the intermediate layer 520 may be modified in one or more suitable manners, such as being integrally formed across a plurality of pixel electrodes 510.

The opposite electrode 530 may be a light-transmitting electrode or a reflective electrode. For example, the opposite electrode 530 may be a transparent or semitransparent electrode and may include a metal thin film having a low work function and including Li, Ca, LiF, Al, Ag, Mg, or a compound thereof. In addition, the opposite electrode 530 may further include a transparent conductive oxide (TCO) film, such as ITO, IZO, ZnO or In₂O₃, located on the metal thin film. The opposite electrode 530 may be formed as a one body over the entire display area where pixels are arranged, and arranged the intermediate layer 520 and the pixel-defining film 119.

### Second Embodiment

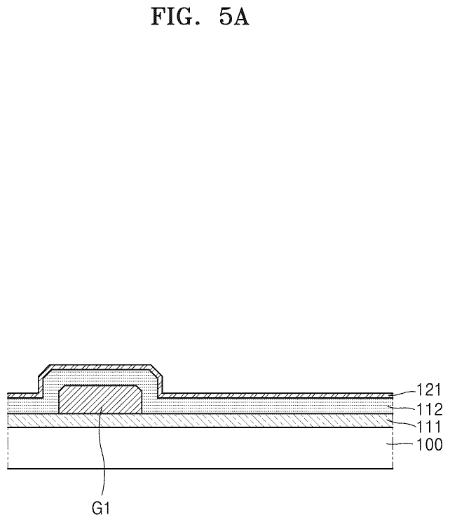

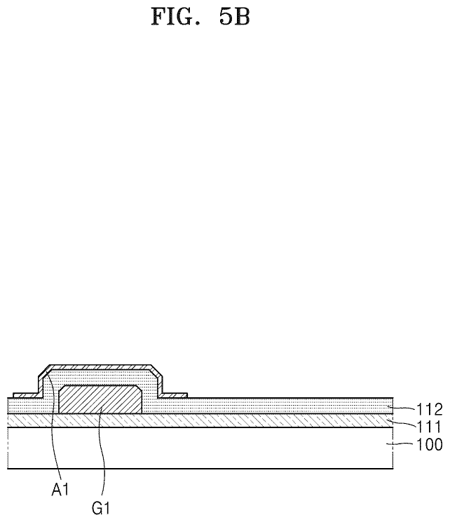

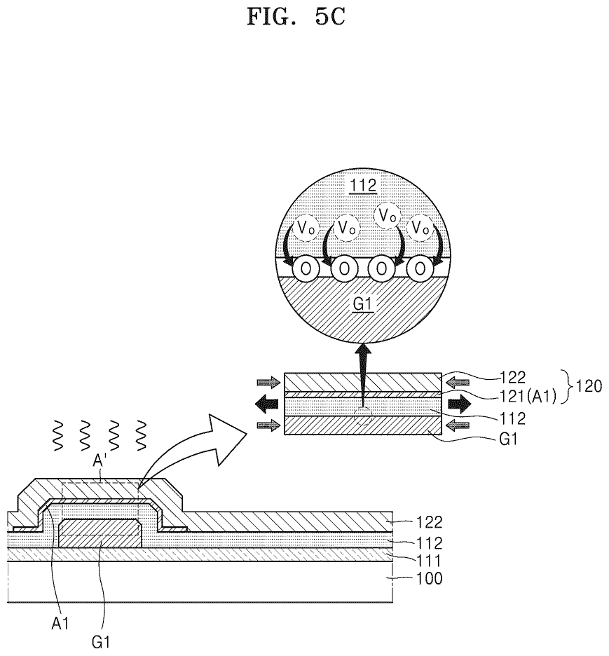

FIGS. 5A to 5C are cross-sectional views illustrating a method of manufacturing the display apparatus 10, according to one or more embodiments.

The embodiments of FIGS. 5A to 5C differ from one or more embodiments of FIGS. 4A to 4H (the first embodiments) described above, in that the semiconductor layer 121 is patterned first and then the second conductive layer 122 is formed.

The second embodiments include an operation of FIG. 5A after the operations of FIG. 4A and FIG. 4B. In addition, the second embodiments include operations of FIGS. 4F to 4H after an operation of FIG. 5C. Hereinafter, differences from the first embodiments will be mainly described with reference to FIGS. 5A to 5C, and redundant descriptions will not be provided as reference may be made to the first embodiments.

Referring to FIG. 5A, the capping layer 120 is formed on the gate insulating layer 112. The capping layer 120 is formed through sputtering or CVD with a conductive material (e.g., an electrically conductive material or conductor) over the entire substrate.

The capping layer 120 may have a multilayer structure including the semiconductor layer 121 formed on the gate insulating layer 112, and the second conductive layer 122 formed on the semiconductor layer 121.

In FIG. 5A, only the semiconductor layer 121 closer to the substrate 100 among the capping layer 120 is formed first, and the second conductive layer 122 is formed after the semiconductor layer 121 is patterned.

The semiconductor layer 121 may include an oxide semiconductor. For example, the semiconductor layer may include IGO (InGaO), IZO (InZnO), ITZO (InSnZnO), IGZO (InGaZnO), and/or the like.

The semiconductor layer may have (e.g., may be formed to) a thickness of 5 nm to 50 nm, or 30 nm. In a case in which the thickness of the semiconductor layer is less than 5 nm, the switching speed or on-off ratio of the element may decrease, resulting in deterioration or reduction of the electrical performance of the element. In a case in which the thickness of the semiconductor layer is greater than 50 nm, a leakage current occurs, resulting in deterioration or reduction of the electrical characteristics of the element.

Referring to FIG. 5B, the semiconductor layer 121 is patterned. The patterned semiconductor layer 121 includes the driving semiconductor area A1 of the first thin-film transistor T1.

The patterning according to one or more embodiments involves the use of another second mask, and the semiconductor area A1 may be formed through wet etching using a diluted hydrochloric acid (HCl) solution, in which HCl and water are mixed in a ratio of 1:10 . . . . P

Referring to FIG. 5C, the second conductive layer 122 is formed on the gate insulating layer 112 to cover the patterned semiconductor area A1.

The second conductive layer 122 includes a conductive material (e.g., electrically conductive material or conductor). The conductive material (e.g., electrically conductive material or conductor) may include a metal, an alloy, a transparent conductive material, and/or the like. In one or more embodiments, the second conductive layer 122 may include a conductive material (e.g., an electrically conductive material or conductor) having a lower (less) coefficient of thermal expansion than ferroelectric materials. In one or more embodiments, the second conductive layer 122 may be a metal layer including one or more materials of (e.g., selected from among) tungsten (W), platinum (Pt), molybdenum (Mo), and/or titanium nitride (TIN).

The second conductive layer 122 may have a single-layer structure or may have a multilayer structure. The second conductive layer 122 may have (e.g., may be formed to) a thickness of 200 nm to 700 nm, but the present disclosure is not limited thereto.

### Third Embodiment

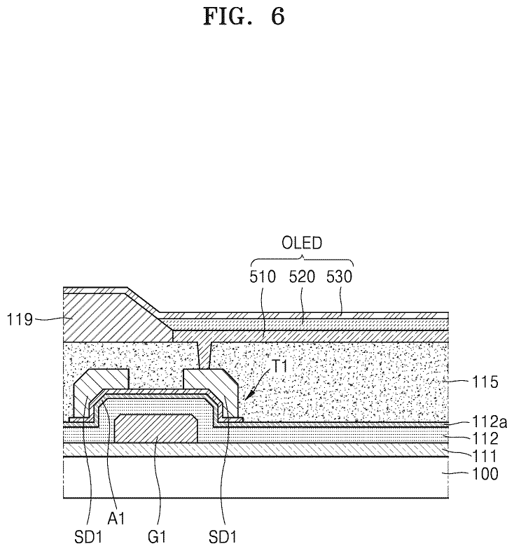

FIG. 6 is a cross-sectional view illustrating the display apparatus 10 according to one or more embodiments.

The embodiment of FIG. 6 is different from one or more embodiments of FIGS. 4A to 4H, i.e., the first embodiments, and one or more embodiments of FIGS. 5A to 5C, i.e., the second embodiments, in that an additional gate insulating layer 112a is further arranged between the gate insulating layer 112 including a ferroelectric material, and the semiconductor layer 121 (A1) including an oxide semiconductor.

The third embodiments further include further forming the additional gate insulating layer 112a after performing the operations of FIGS. 4A and 4B, and include the operations of FIGS. 4C to 4G after the forming of the additional gate insulating layer 112a.

In one or more embodiments, the third embodiments may further include forming the additional gate insulating layer 112a after performing the operations of FIGS. 4A and 4B, and may include the operations of FIGS. 5A to 5C and the operations of FIGS. 4F to 4H after the forming of the additional gate insulating layer 112a.

Hereinafter, differences from the previous embodiments will be mainly described with reference to FIG. 6, and redundant descriptions will not be provided as reference may be made to the previous embodiments.

Referring to FIG. 6, after the operation of FIG. 4B, the additional gate insulating layer 112a is formed on the gate insulating layer 112 including a ferroelectric material. The additional gate insulating layer 112a may include an insulating material. For example, the additional gate insulating layer 112a may include an insulating material having wider (larger) band-gap energy than the ferroelectric material included in the gate insulating layer 112 that is located in a lower portion in the direction toward the substrate 100, or may include the insulating material described above. For example, the insulating material may include silicon dioxide (SiO₂), aluminum oxide (Al₂O₃), and/or the like. In the first thin-film transistor T1 of FIG. 6, if (e.g., when) an electric field is modulated by the gate electrode G1, a channel is formed in the semiconductor area A1 that includes an oxide semiconductor, and a current flows between the source/drain electrodes SD1. In a case in which only the gate insulating layer 112 including the ferroelectric material is present between the gate electrode G1 and the source/drain electrodes SD1, a leakage current occurs toward the gate electrode G1 if (e.g., when) the film characteristics of the gate insulating layer 112 are poor. However, by arranging, between the gate electrode G1 and the source/drain electrodes SD1, the additional gate insulating layer 112a including a material having wider (larger) band-gap energy than ferroelectric materials, this leakage current problem may be prevented or reduced.

The embodiment of FIG. 6 is only an example, and the additional gate insulating layer 112a may be arranged between the gate electrode G1 and the source/drain electrodes SD1, and may be arranged in contact with the upper surface and/or lower surface of the gate insulating layer 112, and one or more suitable modifications are possible.

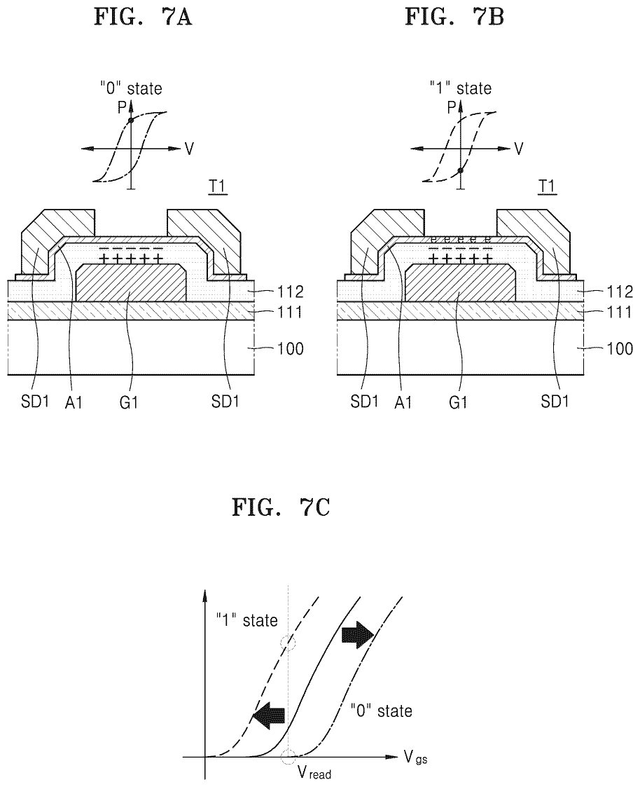

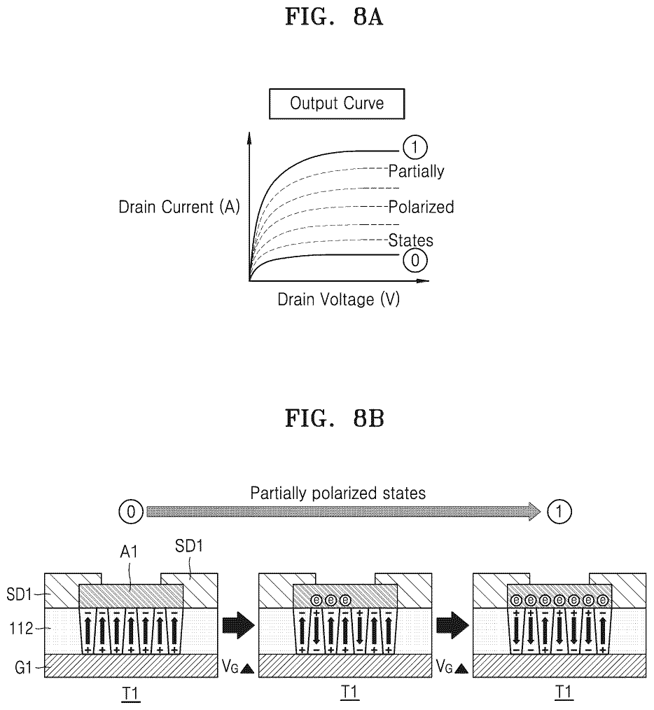

FIGS. 7A-7C and FIGS. 8A and 8B are conceptual diagrams showing the operation principles of a thin-film transistor included in a display pixel circuit, according to one or more embodiments. In FIGS. 8A and 8B, for convenience of description, some components are illustrated as being different from those of the thin-film transistor illustrated in FIG. 4H, for example, the gate insulating layer 112 is illustrated as being thicker and the gate electrode G1 is illustrated as being larger, but the thin-film transistor of FIGS. 8A and 8B is the same as the thin-film transistor of FIG. 4H.

FIGS. 7A-7C and 8A and 8B illustrate the first thin-film transistor T1 of FIG. 4H as an example, and as described above, the first thin-film transistor may be a FeFET. Thus, the first thin-film transistor may perform a memory function through a ferroelectric gate insulator that is spontaneously polarized without an external electric field. When a VG sweep is applied that changes the gate-source voltage in the transistor within a certain range, the first thin-film transistor may maintain its polarization state in the upward or downward direction even if (e.g., when) 0 V is applied.

Referring to FIG. 7A, if (e.g., when) a negative voltage is applied to the gate electrode G1, the first thin-film transistor T1 is in a 0 state and the semiconductor layer (channel) is non-conductive (OFF state). Thus, the polarization of the gate insulating layer 112 including a ferroelectric material makes it difficult for the gate voltage to induce conduction in the channel. Therefore, in the 0 state, almost no drain-source current flows through the first thin-film transistor T1.

Referring to FIG. 7B, if (e.g., when) a positive voltage is applied to the gate electrode G1, the first thin-film transistor T1 is in a 1 state and the semiconductor layer (channel) is conductive (ON state). Thus, the polarization of the gate insulating layer 112 including a ferroelectric material makes it easy for the gate voltage to induce conduction in the channel. Therefore, in the 1 state, a drain-source current flows freely through the first thin-film transistor T1.

Referring to FIG. 7C, the polarization of the ferroelectric material included in the gate insulating layer 112 causes a change in a threshold voltage (Vₜₕ of the first thin-film transistor T1. For example, the threshold voltage of the first thin-film transistor T1 may be variably changed depending on the polarization state of the ferroelectric material. In the present context and unless defined otherwise, the threshold voltage (Vₜₕ) is the minimum gate-to-source voltage (V_{gs}) required to create a conducting path between the source and drain terminals of a field-effect transistor (FET)

Next, referring to FIG. 8A, ‘partially polarized states’ of the first thin-film transistor T1 refer to that the polarization state of the ferroelectric material is in an intermediate state, rather than completely in the 0 state or the 1 state. When the first thin-film transistor T1 is switched from the 0 state to the 1 state during operation, the ferroelectric material transitions completely to state 1 through the intermediate states. This process is reflected in the characteristic curves of drain voltage and drain current.

As illustrated on the left side of FIG. 8B, in the 0 state, the polarization of the ferroelectric material is aligned toward the semiconductor layer (channel) A1. For example, the gate insulating layer 112 including the ferroelectric material has a negative charge toward the semiconductor layer A1 and a positive charge toward the gate electrode G1. In this state, the threshold voltage of the first thin-film transistor T1 increases such that a channel is not formed or the drain current is significantly low.

As illustrated in the center of FIG. 8B, in the partially polarized states, as the gate voltage increases, the ferroelectric material is partially polarized and the drain current begins to gradually increase.

As illustrated on the right side of FIG. 8B, in the 1 state, the polarization of the ferroelectric material is aligned in the opposite direction. The gate insulating layer 112 including the ferroelectric material has a positive charge toward the semiconductor layer A1 and a negative charge toward the gate electrode G1. In this state, the threshold voltage of the first thin-film transistor T1 decreases such that a channel is formed, and the drain current is significantly high.

The first thin-film transistor T1 according to one or more embodiments operates through the polarization characteristics of the ferroelectric material included in the gate insulating layer 112, the polarization characteristics may be maintained even after the electric field is removed, and thus, the first thin-film transistor T1 may also function as a storage element. Accordingly, the display pixel circuit PC according to one or more embodiments uses a FeFET as a driving thin-film transistor, thus, a capacitor that stores a voltage corresponding to a data signal inside the pixel circuit PC may be removed, and accordingly, the size of the pixel circuit PC may be reduced.

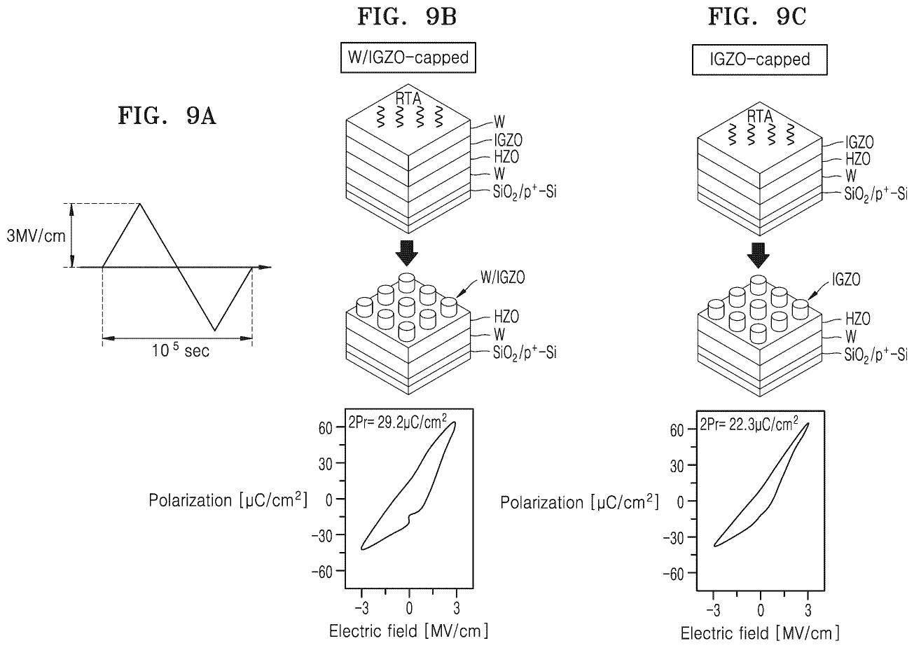

FIGS. 9A-9C are conceptual diagrams showing a result of an experiment conducted to determine the characteristics of a gate insulating layer of a thin-film transistor included in the display pixel circuit PC according to one or more embodiments, compared with a comparative example.

Referring to FIGS. 9A-9C, in order to confirm the characteristics of the gate insulating layer 112 of the first thin-film transistor T1 of FIG. 4H according to the present disclosure, as one or more embodiments, a barrier layer made of silicon oxide (SiO₂) was formed on a P-type (kind) silicon substrate (P⁺—Si), a gate electrode made of tungsten (W) was formed on the barrier layer, a gate insulating film including a ferroelectric material (HZO) was formed on the gate electrode, and a capping layer was formed on the gate insulating film, wherein the capping layer included a semiconductor layer located on the gate insulating film and including an oxide semiconductor (IGZO), and a metal layer made of tungsten (W) on the semiconductor layer. In the comparative example, the capping layer included only a semiconductor layer including an oxide semiconductor. Other aspects of the comparative example were substantially identical to one or more embodiments of the present disclosure. In FIGS. 9A-9C, the layers are represented not by separate reference numerals but by their materials.

As shown in FIG. 9A, an alternating-current voltage of 3 MV/cm at 100 KHz was applied to the thin-film transistors of one or more embodiments and the comparative example, and then changes in the polarization of one or more embodiments and the comparative example according to the voltage were measured to record a polarization-electric field (P-E) hysteresis curve, which is a relationship between an electric field (E) and polarization (P). Remanent polarization (Pr), which is a polarization value at a point where the electric field is 0 in the P-E hysteresis curve, was derived, and the main properties of the ferroelectric material were evaluated based on the derived remanent polarization.

As shown in FIG. 9B, the remanent polarization of one or more embodiments is 29.2 μC/cm², and as shown in FIG. 9C, the remanent polarization of the comparative example is 22.3 μC/cm². For example, it may be confirmed that the remanent polarization of one or more embodiments is higher than the remanent polarization of the comparative example.

For example, it may be confirmed that a multi-capping layer including a semiconductor layer and a metal layer according to one or more embodiments imparts improved ferroelectricity to a gate insulating layer compared to a mono-capping layer.

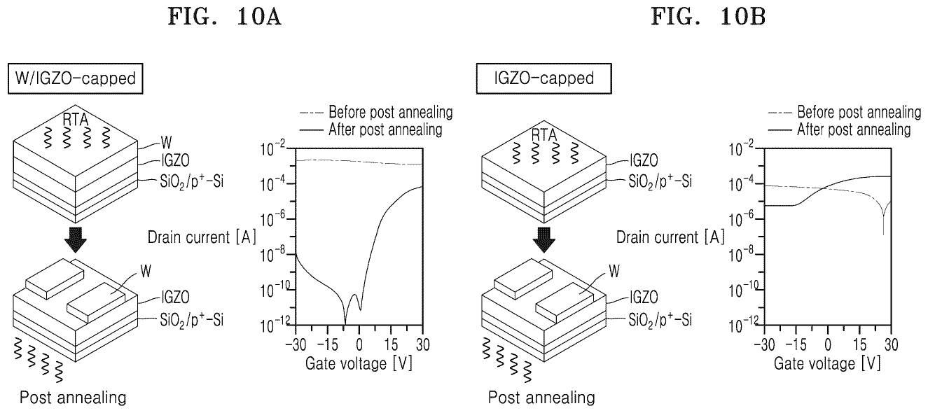

FIGS. 10A and 10B are conceptual diagrams showing a result of an experiment conducted to determine the characteristics of a semiconductor layer of a thin-film transistor included in a display pixel circuit according to one or more embodiments, compared with a comparative example.

Referring to FIGS. 10A and 10B, in order to confirm the characteristics of the semiconductor layer of the first thin-film transistor of FIG. 4H according to the present disclosure, as one or more embodiments, a barrier layer made of silicon oxide (SiO₂) was formed on a P-type (kind) silicon substrate (P⁺—Si), and a semiconductor layer including an oxide semiconductor (IGZO) and a metal layer made of tungsten (W) was arranged on the semiconductor layer. In the comparative example, the capping layer included only a semiconductor layer including an oxide semiconductor. Other aspects of the comparative example were substantially identical to one or more embodiments of the present disclosure. In FIGS. 10A and 10B, as in FIG. 9, the layers are represented not by separate reference numerals but by their materials.

As shown in 10A, in one or more embodiments, a multi-capping layer including a semiconductor layer and a metal layer was formed, then a primary heat treatment process was performed to heat the multi-capping layer at about 500° C. for about 30 seconds in a nitrogen environment and then immediately cool the multi-capping layer at room temperature, then source/drain electrodes were patterned, and then a secondary heat treatment process was performed. In the comparative example, as shown in FIG. 10B, the primary heat treatment process and the secondary heat treatment process were performed under the same conditions in substantially the same environment. Then, by measuring the drain current (I_{D}) according to the gate voltage (V_{G}), the on-off ratio, which is the ratio of the maximum drain current in the ON state to the minimum drain current in the OFF state, was confirmed.

Referring to FIG. 10A, in one or more embodiments, it may be confirmed that the semiconductor layer exhibited metallic properties before the secondary heat treatment, but after the secondary heat treatment, the semiconductor layer exhibited semiconductor properties suitable for a thin-film transistor with an on-off ratio of about 10⁸.

Referring to FIG. 10B, in contrast, in the comparative example, it may be confirmed that the semiconductor layer exhibited metallic properties before the secondary heat treatment and did not exhibit semiconductor properties even after the secondary heat treatment.

For example, it may be confirmed that the first thin-film transistor manufactured by the manufacturing process according to one or more embodiments of the present disclosure is an element having appropriate or suitable semiconductor properties.

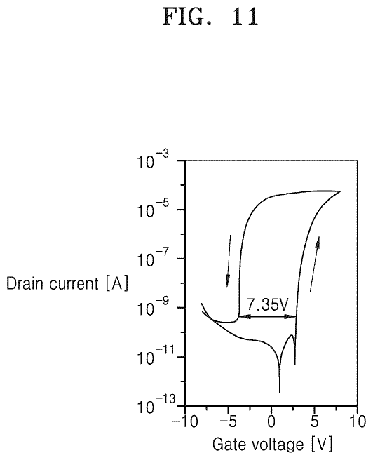

FIG. 11 is a conceptual diagram showing a result of an experiment conducted to determine the element characteristics of a thin-film transistor included in a display pixel circuit according to one or more embodiments, compared with a comparative example.

Referring to FIG. 11, in order to confirm the element characteristics of the first thin-film transistor T1 of FIG. 4H according to the present disclosure, parameters, such as a memory window value, an on-off ratio, and a subthreshold swing (SS) value of the first thin-film transistor T1 were measured.

As shown in FIG. 11, the memory window value of the first thin-film transistor was measured to be 7.35 V, confirming that the ferroelectric properties of the element were clearly exhibited. In addition, the on-off ratio of the first thin-film transistor was measured to be 1.57×10⁸, confirming that the leakage current was minimized or reduced and that the first thin-film transistor had excellent or suitable current-blocking capabilities. In addition, the programmed subthreshold of the first thin-film transistor was 0.16 V/dec and the erased subthreshold was 0.14 V/dec, confirming that the first thin-film transistor has excellent or suitable switching speed and efficiency due to its low subthreshold swing.

For example, the process of manufacturing of a pixel circuit according to one or more embodiments may enable manufacture of a pixel circuit including a high-performance FeFET through a simplified process.

The display apparatus 10 according to one or more embodiments described above may be applied to an electronic apparatus as a display module.

As a specific example, the electronic apparatus of the present embodiment may include the display apparatus 10 described above, as a display module, and may further include one or more of (e.g., selected from among) a processor, a memory, an input module, a power module, an embedded module, and/or an external module.

The processor may execute software stored in the memory to control at least one of other components (e.g., a hardware or software component) of the electronic apparatus connected to the processor, and may perform one or more suitable operations for data processing or computation.

The processor may include a main processor and an auxiliary processor. The main processor may include one or more of (e.g., selected from among) a central processing unit (CPU), an application processor (AP), a graphics processing unit (GPU), a communication processor (CP), an image signal processor (ISP), and/or a neural processing unit (NPU). The auxiliary processor may include a controller (e.g., 13 of FIG. 1). The controller receives an image signal from the main processor, converts the data format of the image signal to match the interface specifications with the display apparatus, and outputs the image data. The controller may output one or more suitable control signals necessary for driving the display apparatus. The operations of the controller and the display apparatus are described above with reference to FIG. 1, and thus, redundant descriptions will not be provided.

The memory may store one or more suitable pieces of data used by at least one component of the electronic apparatus (e.g., the processor) and input data or output data for instructions related thereto. The memory may include at least one of a volatile memory or a non-volatile memory.

The input module may receive commands or data from outside the electronic apparatus (e.g., a user or an external electronic apparatus) to be used by a component of the electronic apparatus (e.g., the processor, a sensor module, or an audio output module).

The power module provides power to the components of the electronic apparatus. The power module may include a battery.

The electronic apparatus may further include built-in modules and external modules. The embedded modules may include a sensor module, an antenna module, and an audio output module. The external modules may include a camera module, a light module, and a communication module.

The electronic apparatus may include (e.g., may be of) one or more suitable forms. The electronic apparatus may include, for example, at least one of a portable communication device (e.g., a smart phone), a computer device, a portable multimedia device, a portable medical device, a camera, a wearable device, a virtual reality device, a virtual reality system, or a home appliance. The electronic apparatus according to one or more embodiments is not limited to the above examples.

According to one or more embodiments, there may be provided a display apparatus in which the size of a pixel circuit is reduced. In addition, according to one or more embodiments, there may be provided a method of manufacturing a display apparatus with a simplified process. However, the scope of the present disclosure is not limited by the above effects.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

Each of one or more embodiments described above may be implemented independently, but the structure of each embodiment may be applied to one or more embodiments in combination.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Although the present disclosure has been described with reference to one or more embodiments shown in the drawings, which are merely examples, it will be understood by those skilled in the art that one or more suitable modifications and equivalent one or more embodiments are possible therefrom. Accordingly, the true technical protection scope of the present disclosure should be defined by the technical spirit of the appended claims.

The particular implementations shown and described herein are illustrative examples of one or more embodiments and are not intended to otherwise limit the scope of one or more embodiments in any way. In addition, no item or component is essential to the practice of the present disclosure unless the item or component is specifically described as being “essential” or “critical”.

The term “the” and other demonstratives similar thereto in the descriptions of embodiments (especially in the following claims and equivalents thereof) should be understood to include a singular form and plural forms. Further, recitation of ranges of values herein are merely intended to serve as a shorthand method of referring individually to each separate value falling within the range, unless otherwise indicated herein, and each separate value is incorporated into the specification as if it were individually recited herein. Finally, operations of all methods described herein can be performed in any suitable order unless otherwise indicated herein or otherwise clearly contradicted by context. The embodiments are not limited to the described order of the operations. The use of any and all examples, or example language in embodiments, is intended merely to better illuminate one or more embodiments and does not pose a limitation on the scope of one or more embodiments unless otherwise claimed. Also, numerous modifications and adaptations will be readily apparent to those skilled in the art without departing from the spirit and scope of the present disclosure.

What is claimed is:

1. A method of manufacturing a display pixel circuit,
the display pixel circuit comprising a switching thin-film transistor, a driving thin-film transistor connected to the switching thin-film transistor, and a light-emitting element connected to the driving thin-film transistor,
the method comprising:
forming the driving thin-film transistor; and
forming the light-emitting element connected to the driving thin-film transistor,
wherein the forming of the driving thin-film transistor comprises:
forming a gate electrode;
forming a gate insulating layer comprising a ferroelectric material on the gate electrode;
forming a capping layer comprising a semiconductor layer on the gate insulating layer, and a metal layer on the semiconductor layer, wherein the semiconductor layer comprises an oxide semiconductor;
configuring the gate insulating layer to exhibit ferroelectricity, through a primary heat treatment process; and
forming source/drain electrodes by patterning the metal layer.

2. The method of claim 1, further comprising, after the forming of the source/drain electrodes:
patterning the semiconductor layer; and
activating the semiconductor layer through a secondary heat treatment process.

3. The method of claim 2, wherein the forming of the source/drain electrodes and the patterning of the semiconductor layer are performed by utilizing a halftone mask.

4. The method of claim 1, further comprising:
before the forming of the metal layer, patterning the semiconductor layer; and
after the forming of the source/drain electrodes, activating the semiconductor layer through a secondary heat treatment process.

5. The method of claim 2, wherein the primary heat treatment process is performed at a first temperature for a first period of time, and
the secondary heat treatment process is performed at a second temperature that is lower than the first temperature, for a second period of time that is longer than the first period of time.

6. The method of claim 1, wherein the ferroelectric material comprises hafnium zirconium oxide (HZO), and
the gate electrode and the metal layer each comprise a material having a thermal expansion coefficient less than a thermal expansion coefficient of the ferroelectric material.

7. The method of claim 1, wherein the gate insulating layer is formed by utilizing at least one deposition method of an atomic layer deposition method, a sputtering deposition method, or a spin coating deposition method.

8. The method of claim 1, wherein the oxide semiconductor comprises at least one material of InGaO (IGO), InZnO (IZO), InSnZnO (ITZO), or InGaZnO (IGZO).

9. The method of claim 1, wherein a thickness of the semiconductor layer is about 5 nm to about 50 nm.

10. The method of claim 1, wherein a thickness of the gate insulating layer is about 10 nm to about 20 nm.

11. The method of claim 1, further comprising, after the forming of the gate insulating layer, forming an additional gate insulating layer between the gate insulating layer and the semiconductor layer,
wherein the additional gate insulating layer comprises a dielectric material having a wider band gap than a band gap of the ferroelectric material.

12. The method of claim 11, wherein the additional gate insulating layer comprises at least one material of silicon dioxide (SiO₂) or aluminum oxide (Al₂O₃).

13. The method of claim 1, wherein the gate electrode and the metal layer each comprise at least one material of tungsten (W), platinum (Pt), molybdenum (Mo), or titanium nitride (TiN).

14. A display pixel circuit comprising:
a switching thin-film transistor;
a driving thin-film transistor connected to the switching thin-film transistor; and
a light-emitting element connected to the driving thin-film transistor,
wherein the driving thin-film transistor comprises:
a gate electrode;
a semiconductor layer comprising an oxide semiconductor;
a gate insulating layer between the gate electrode and the semiconductor layer and comprising a ferroelectric material; and
source/drain electrodes on the semiconductor layer,
wherein the ferroelectric material comprises hafnium zirconium oxide (HZO), and
wherein the gate electrode and the source/drain electrodes each comprise a material having a thermal expansion coefficient less than a thermal expansion coefficient of the ferroelectric material.

15. The display pixel circuit of claim 14, wherein the oxide semiconductor comprises at least one material of InGaO (IGO), InZnO (IZO), InSnZnO (ITZO), or InGaZnO (IGZO).

16. The display pixel circuit of claim 14, wherein a thickness of the semiconductor layer is about 5 nm to about 50 nm.

17. The display pixel circuit of claim 14, wherein a thickness of the gate insulating layer is about 10 nm to about 20 nm.

18. The display pixel circuit of claim 14, further comprising an additional gate insulating layer between the gate insulating layer and the semiconductor layer, wherein the additional gate insulating layer comprises a dielectric material having a wider band gap than a band gap of the ferroelectric material.

19. The display pixel circuit of claim 18, wherein the additional gate insulating layer comprises at least one material of silicon dioxide (SiO₂) or aluminum oxide (Al₂O₃).

20. An electronic apparatus comprising a display module, wherein
the display module comprises a display pixel circuit,
the display pixel circuit comprises: a switching thin-film transistor; a driving thin-film transistor connected to the switching thin-film transistor; and a light-emitting element connected to the driving thin-film transistor,
the driving thin-film transistor comprises: a gate electrode; a semiconductor layer comprising an oxide semiconductor; a gate insulating layer between the gate electrode and the semiconductor layer and comprising a ferroelectric material; and source/drain electrodes on the semiconductor layer,
the ferroelectric material comprises hafnium zirconium oxide (HZO), and
the gate electrode and the source/drain electrodes each comprise a material having a thermal expansion coefficient less than a thermal expansion coefficient of the ferroelectric material.
